(19) United States
(12) Patent Application Publication
(10) Pub. No.: US 2010/0078804 A1
(43) Pub. Date: Apr. 1, 2010

(54) Apparatus with Side Mounted Microchip

(75) Inventor: Alvin Grusby, Newton, MA (US)

Correspondence Address: Sunstein Kann Murphy & Timbers LLP, 125 SUMMER STREET, BOSTON, MA, 02110-1618, US

(73) Assignee: ANALOG DEVICES, INC., Norwood, MA (US)

(21) Appl. No.: 12/240,581

(22) Filed: Sep. 29, 2008

(51) Int. Cl. H01L 23/02

(52) U.S. Cl. 257/698; 257/E23.18

(57) ABSTRACT

In accordance with one embodiment of the invention, a packaged microchip has 1) a base with a mounting surface having a given electrical interconnector, and 2) a microchip with a plurality of side surfaces, a top surface, a bottom surface, and a given electrical pad on at least one of the top and bottom surfaces. The packaged microchip also has 3) a given solder ball secured to one of the top and bottom surfaces of the microchip. The given solder ball also is connected to the given electrical interconnector to electrically connect the given electrical pad and the given electrical interconnector. At least one side surface of the microchip is generally parallel with the mounting surface of the base.

### FIELD OF THE INVENTION

The invention generally relates to microchips and, more particularly, the invention relates to microchip mounting and orientation.

### BACKGROUND OF THE INVENTION

The high-tech industry often strives to balance two competing goals; namely, increasing device functionality while reducing overall device size. For example, over the past several years, mobile telephone functionality has increased exponentially while their average size has decreased. To accomplish these goals, some system designers have been using smaller components, with improved or at least similar functionality, for mounting on smaller and smaller circuit boards.

Another known technique for adding functionality while reducing size/chip footprint secures the side surface of a so-called “daughterboard” (with a plurality of circuit components) to a primary circuit board. The primary circuit board, which often is referred to as a “motherboard,” also has a plurality of additional components that cooperate with the daughterboard to accomplish pre-specified functions. Another known technique mounts the side of a specialized microchip package to a circuit board.

While useful in many applications, these techniques have drawbacks. For example, the daughterboard technique requires a board-level mounting process and extra system components. In a similar manner, the side-mounted package technique requires a specialized package (i.e., side-mount packages rather than conventional, widely used bottom-mount packages).

### SUMMARY OF THE INVENTION

In accordance with one embodiment of the invention, a packaged microchip has 1) a base with a mounting surface having a given electrical interconnector, and 2) a microchip with a plurality of side surfaces, a top surface, a bottom surface, and a given electrical pad on at least one of the top and bottom surfaces. The packaged microchip also has 3) a given solder ball secured to either the top or bottom surface of the microchip. The given solder ball also is connected to the given electrical interconnector to electrically connect the given electrical pad and the given electrical interconnector. At least one side surface of the microchip is generally parallel with the mounting surface of the base.

The given solder ball may connect between the top surface of the microchip and the base, while a second solder ball may secure between the bottom surface of the microchip and the base. The second solder ball thus may electrically connect a second electrical interconnector (of the base) with a second electrical pad (of the microchip bottom surface).

The microchip also may have a via extending between the top and bottom surfaces. In such case, the via, given electrical pad, given solder ball, and given electrical interconnector may form a conductive path. In a similar manner, the base may have a base via that includes the given electrical interconnector. The base via may electrically connect with the conductive path.

The microchip may implement any of a wide variety of microchip technologies, such as that of a MEMS device. To protect the MEMS device, the microchip also may have a cover, secured to the base, to form a cavity that contains the microchip. Of course, the microchip may use a cover with non-MEMS microchips. Moreover, in addition to the microchip, the base also may have additional components.

Among other ways, one of the microchip side surfaces may be mounted generally flush with the mounting surface of the base. In addition, or in the alternative, the side surface that is generally parallel with the mounting surface illustratively is free of electrical pads (e.g., pads that connect with functionality within the microchip). Moreover, the base may be any of a variety of different technologies, such as a substrate, a carrier, or a laminate.

In accordance with another embodiment of the invention, an apparatus has a circuit board having a mounting surface with a given electrical interconnector, and a microchip having a plurality of side surfaces, a top surface, and a bottom surface. The microchip also has a given electrical pad on at least one of the top and bottom surfaces. One of the microchip side surfaces is generally parallel with the mounting surface of the circuit board. The apparatus further has a given solder ball secured to one of the top and bottom surfaces. The given solder ball also is connected to the mounting surface and electrically connects the given electrical pad of the microchip and the given electrical interconnector of the circuit board.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a circuit board having a plurality of components, including a packaged microchip configured in accordance with illustrative embodiments of the invention.

FIG. 2 schematically shows a perspective, exterior view of a packaged microchip configured in accordance with illustrative embodiments of the invention.

FIG. 3 schematically shows a cross-sectional view of the packaged microchip of FIG. 2 along line X-X in accordance with one embodiment of the invention.

FIG. 4 schematically shows a cross-sectional view of the packaged microchip of FIG. 2 along line X-X in accordance with one embodiment of the invention.

FIG. 5 shows a process for packaging the microchip in accordance with illustrative embodiments of the invention.

### DESCRIPTION OF ILLUSTRATIVE EMBODIMENTS

Illustrative embodiments form a packaged microchip by mounting a die in a vertical orientation; namely, with its side surface generally parallel with the base of the package. Accordingly, this type of packaged microchip may have a smaller footprint or, among other things, a similar footprint but more internally mounted components. To that end, various embodiments secure solder balls along the top and bottom surfaces of the die to both electrically and mechanically secure it to the package base. More specifically, the solder balls electrically connect a pad on at least one of the top and bottom surfaces of the die with a perpendicularly oriented interconnect/pad on the die. Details of illustrative embodiments are discussed below.

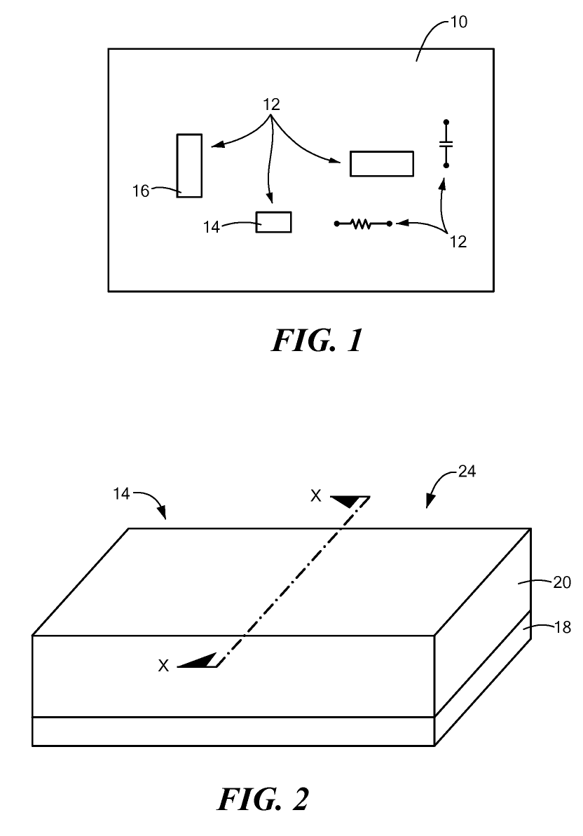

FIG. 1 schematically shows a circuit board 10 having a plurality of circuit components 12, including a packaged microchip 14 configured in accordance with illustrative embodiments of the invention. The circuit board 10 may be mounted within any of a number of different devices, such as within a cellular telephone, computer, automobile, television, or other electronic device. Among other things, other components 12 on the circuit board 10 may include capacitive elements, resistive elements, other microchips (e.g., microprocessors, MEMS devices, ASICs, etc. . . . ). In some embodiments, instead of, or in addition to, the noted packaged microchip 14, the circuit board 10 has a vertically mounted die 16 (discussed in greater detail below and shown in different levels of detail by FIGS. 1-4).

FIG. 2 schematically shows an exterior, perspective view of a packaged microchip 14 configured in accordance with illustrative embodiments of the invention. From this view, the packaged microchip 14 has a base 18 and a covering 20 (e.g., a lid/cover, Glop Top, or mold compound, discussed below and identified by reference number 20) that protects the interior components 12.

Among other things, a substrate, such as the material used in a substrate package (e.g., FR-4 or other printed circuit board material) may form the base 18. Alternatively, a ceramic substrate, a laminate (e.g., BT resin or LGA laminate), a leadframe base, or a conventional carrier may form the base 18. Those skilled in the art may use other types of bases and thus, the types discussed above merely are illustrative of specific embodiments and, consequently, not intended to limit other embodiments.

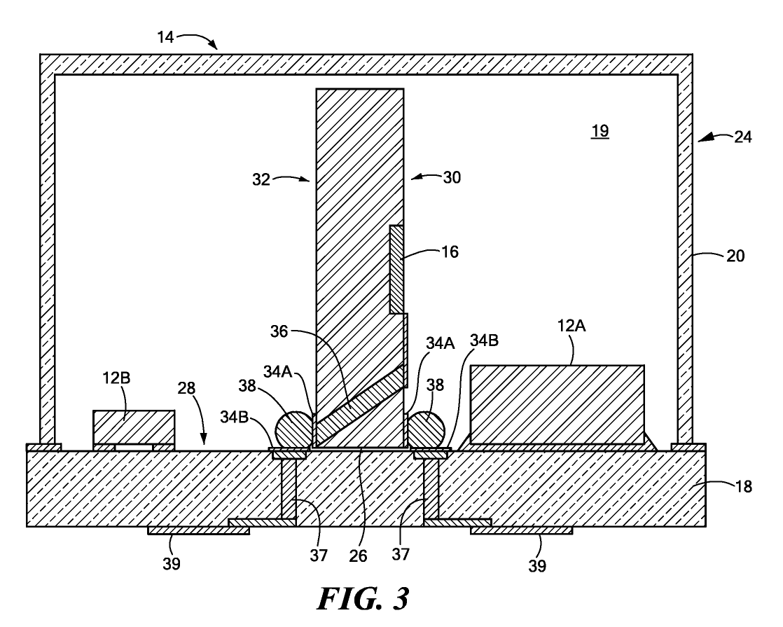

FIG. 3 schematically shows a cross-sectional view of the packaged microchip 14 of FIG. 2 along line X-X in accordance with one embodiment of the invention. As shown, this embodiment orients a die 16 in a manner that enables a plurality of other components 12 to be mounted within a single package 24 without increasing its footprint. To that end, the packaged microchip 14 has the noted base 18, which supports a plurality of circuit components 12, such as 1) a die 12A mounted in a conventional, bottom-side down configuration or in a flip-chip manner, and 2) a discrete component 12B (e.g., a capacitor or resistor). Although not shown, the base 18 also may support other types of components 12, such discrete circuit elements (e.g., passive and active electronics).

A lid 20 secured to the base 18 forms a cavity/chamber 19 and protects the interior circuit components 12. Among other things, the lid 20 may be formed of metal, plastic, or some other material conventionally used in packaging applications.

In accordance with illustrative embodiments of the invention, the packaged microchip 14 also has a least one die 16 with its side surface 26 generally parallel to the top, mounting surface 28 of the base 18. The die top and bottom surfaces 30 and 32 (i.e., the opposing surfaces in the die 16 shown with the largest surface areas) are generally perpendicular to the base 18. The die 16 may implement any of a number of different functionalities, including those of a MEMS device (e.g., an inertial sensor or microphone), a microprocessor, an ASIC, or other type of conventional microchip.

The noted vertically mounted die 16 is identified by reference number 16. When grouped with other components but not specifically mentioned, however, the die 16 is identified generally by the reference number 12.

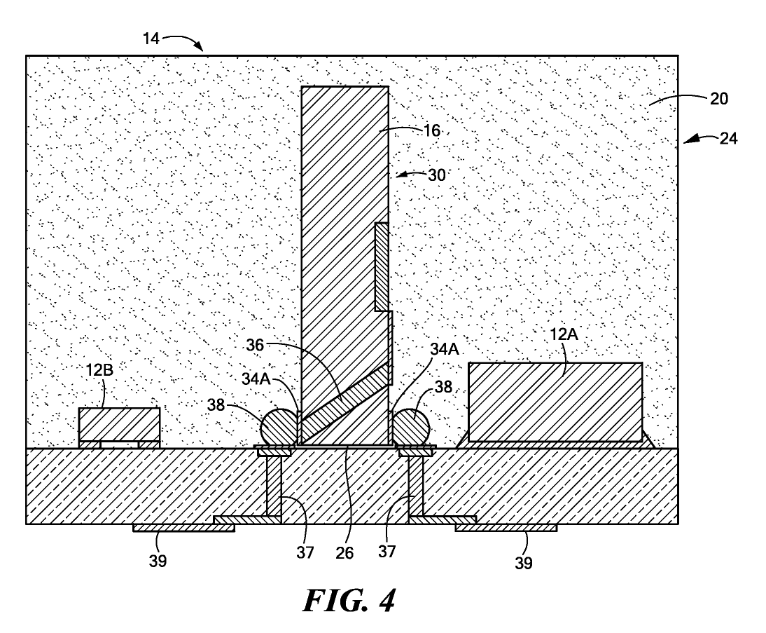

To electrically connect with other devices, the die 16 has a plurality of pads 34A on its top and bottom surfaces 30 and 32. Optionally, illustrative embodiments have one or more vias 36 through the die 16. Among other things, these vias 36 can connect the pads 34A of both surfaces 30 and 32. For example, FIGS. 3 and 4 show angled vias 36. Of course, the inventor also contemplates use of straight vias 36. Alternative embodiments, however, may have pads 34A on only one of those two surfaces 30 and 32. In a corresponding manner, the base 18 also has a plurality of pads 34B (also referred to as “interconnects”) for electrically transmitting signals between the die 16 and external components (or other components 12 within the packaged microchip 14). The base 18 therefore also has base vias 37, which electrically connect to surface mounting pads 39 external to the package 24.

The die pads 34A thus are generally perpendicular to the base pads 34B. As known by those in the art, making the electrical connection between these respective pads 34A and 34B with conventional wirebond and related techniques is very difficult. Despite this challenge, the inventor discovered that solder balls can provide an appropriate electrical connection without increasing the complexity of the packaging process. Accordingly, as shown in FIG. 3, illustrative embodiments mount a plurality solder balls 38 to one or both of the top and bottom surfaces 30 and 32 of the die 16—near the die side 26 that is closest to and generally parallel with the base 18. The vias 36 within the die 16 and/or circuit traces on the surfaces 30 and 32 direct electrical signals to the die pads 34A and, ultimately, to the base pads 34B through the solder balls 38.

In addition to presenting electrical connection challenges, illustrative embodiments also presented the inventor with die stability challenges—both during packaging and in the finished packaged microchip 14. More specifically, as noted above, as dies become smaller, their corresponding side surfaces also become even smaller. For example, the die 16 may have a thickness of about 0.3-0.4 millimeters. A side 26 mounted die 16 thus appeared to be relatively unstable when compared to conventional bottom-mount die configurations. Despite this disincentive, the inventor further discovered that in addition to providing electrical connections, the solder balls 38 also securely stabilized the die 16 on the base 18. The solder balls 38 thus can stabilize the die 16 both during packaging, and in the finished packaged microchip 14.

Rather than forming an open cavity/chamber 19 within the packaged microchip 14, some embodiments overmold the base 18 and its components 12 with mold material. FIG. 4 schematically shows one such embodiment. The choice of a lid 20 or overmolding depends upon the application. For example, an application using an uncapped MEMS device should use the lid embodiment, while a packaged microchip 14 with only ASICs generally may use the overmolded embodiment. As another example, applications that require hermeticity may use the lid embodiment.

Alternative embodiments do not have all the additional components 12. Instead, such embodiments may simply have the single, vertically mounted die 16. Accordingly, such embodiments may have a much smaller footprint than conventional die mounting configurations.

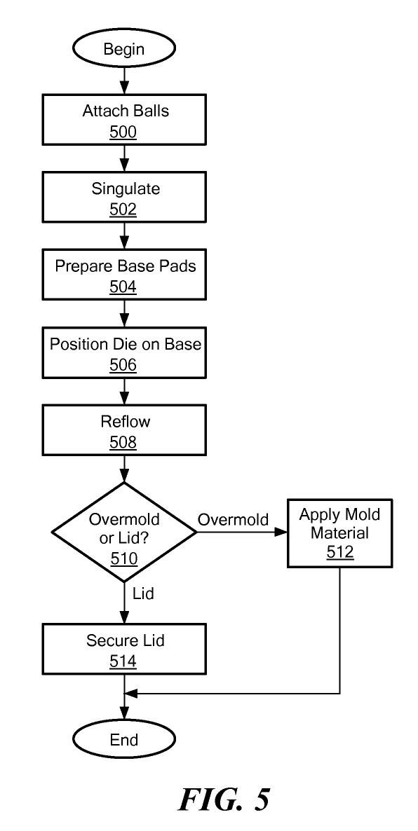

FIG. 5 shows a process of forming the packaged microchips 14 shown in FIGS. 2-4 in accordance with illustrative embodiments of the invention. It should be noted that this process is a summary of a much longer process and thus, may omit certain steps. For example, the process does not discuss methods of electrically connecting additional components 12 with wirebonds, solder, or other known techniques. In addition, this process may perform some of the steps in an order that is different than that discussed. For example, certain steps may be implemented substantially simultaneously, or in a different order than that discussed.

The process is discussed as being performed using batch fabrication processes. Thus, the process begins at step 500, which attaches solder balls 38 to a larger wafer (not shown) that is pre-processed to have a plurality of functional dies. For example, the solder paste 38 may be formed from 95.5 percent tin, 3.9 percent silver, and 0.6 percent copper (generally known as “SAC396”). Of course, other combinations of materials should suffice and thus, the noted combination merely is illustrative of one type that may be used in some applications.

For improved stability, preferred embodiments deposit the solder balls 38 on the wafer along both long sides/surfaces of each die 16 (i.e., as shown in the figures). Both sides of the wafer thus have solder balls 38. Accordingly, as discussed below and shown in FIGS. 3 and 4, the finished packaged microchip 14 has solder balls 38 near the first long edge formed by the top die surface 30 and side die surface 26, and near the other long edge formed by the bottom die surface 32 and the same side die surface 26. Other embodiments may position solder balls 38 on only one side of the die 16. The other side can either be free of any material or mechanical structure for supporting the die 16, or have other mechanical structure to support the die 16. For example, one side of the die 16 can have solder balls 38 while the other side can have a support bracket.

Next, the process singulates the wafer to form a plurality of individual dies that each have solder balls 38 secured in a manner that, as discussed above and below, facilitates side mounting (step 502). Conventional sawing or laser dicing techniques, among other things, may be used. Alternative embodiments may attach the solder balls 38 on each individual die 16 after singulation—not before singulation as described in FIG. 5.

The process then prepares the base pads 34B to bond with the solder balls 38 (step 504). To that end, conventional process may apply a tacky flux and, in some embodiments, solder paste to the base pads 34B. Consequently, the base bond pads 34B should appropriately bond with the solder balls 38.

As an example, among other types, some embodiments may use Kester Type TSF-6850 tacky flux for this application. In addition to performing its primary function, the tacky flux also causes the mounting surface 28 of the base 18 to become sticky. As discussed below, this sticky mounting surface 28 facilitates processing.

The process then continues to step 506, which positions the die 16 and other components 12 on the base 18; namely, this step positions the side surface 26 of the die 16 onto the mounting surface 28 of the base 18. In some embodiments, the base 18 has a cut groove for receiving the side surface 26 of the die 16. Moreover, the side surface 26 may be flush and in contact against the base 18. Alternatively, the contour of the base 18 (e.g., a groove), die 16, or intervening element may cause the side surface 26 not to be flush against the base 18. In either case, the side surface 26 should be generally parallel with the majority of the mounting surface 28 of the base 18.

The tacky flux causes the side surface 26 of the die 16 to stick to the base 18 as it continues to the next stage of processing. In addition, the solder balls 38 also at least partially stabilize the die 16. Accordingly, the combination of the solder balls 38 and tacky flux should provide sufficient stability during the rest of the packaging process. Some embodiments may apply adhesive to the base 18 to further stabilize the die 16. The adhesive may be used instead of, or in addition to, the tacky flux or fixture.

If the die 16 is rectangular, then any side surface 26 (i.e., not the top or bottom surfaces 30 and 32 of the die 16) may face downwardly toward the base 18. If the die 16 is another shape, then any thin side surface 26 may face downwardly toward the base 18. In various embodiments, the side 26 facing downwardly has no pads 34A (i.e., it is free of electrical contacts). Alternatively, such side 26 can have one or more pads 34A that are or, in some cases, are not electrically connected with the base 18.

After positioning the die 16, the apparatus reflows the solder balls 38 (step 508). Among other ways, high-volume packaging processes may move the base 18 and accompanying components 12 into a reflow furnace. The furnace should be set to temperatures that are high enough to reflow the solder balls 38, but low enough to not adversely impact the components 12. If it were not sufficiently secured to the base 18 by the tacky flux, adhesive, and/or solder balls 38, it is very likely that this movement would cause the die 16 to fall from its side mounted orientation. Accordingly, the tacky flux, adhesive, and/or solder balls 38 secure the die 16 to facilitate packaging.

This step also effectively causes the solder balls 38 to form a continuous connection between the pads 34A and 34B on both the die 16 and the base 18, thus also electrically connecting the die 16 with the base 18. It should be noted that the solder balls 38 are not necessarily spherically shaped. Instead, the solder balls 38 may take on any of a number of different shapes and configurations sufficient to perform the underlying functions. During experiments, multiple solder balls 38 mounted along the top and bottom surfaces 30 and 32 as described and having about a 300 micron diameter adequately supported a die 16 having a thickness of about 0.35 millimeters.

The method then determines how to protect the components 12 mounted on the base 18 (step 510). Of course, this is a function of a number of variables, including the intended application and cost. For example, as noted above, if the components 12 mounted on the base 18 have no exposed movable or otherwise sensitive parts, then the process may overmold the device by applying a mold material using a conventional molding process (step 512) or add underfill. Alternatively, the process may secure lid 20 to the base 18 (step 514). To that end, the lid 20 may have one or more sidewalls that, using conventional processes, secures to the base 18. For example, adhesive or solder may secure the lid 20 to the base 18. It should be noted that a lid 20 may be used even when the components 12 have no exposed, sensitive parts.

The specific lid 20 described and shown in FIG. 3 is but one of many different types of lids 20 that the process may use. For example, the lid 20 could be flat and thus, rest on one or more walls extending from the base 18. The walls can be formed by additional components 12, or a part of the base 18.

Various embodiments also apply to dies coupled directly with a circuit board of a larger system. For example, the die 16 may be vertically mounted to the circuit board 10 shown in FIG. 1, which then may be mounted within a computer system. Accordingly, such a die 16 has no cover, base 18, or molding material. The circuit board 10 thus performs the function of the base 18 in that instance.

Accordingly, illustrative embodiments of the invention vertically mount one or more dies 16 within a package 24 to reduce the overall package footprint, or to include more components 12 within a single package 24. Other embodiments mount one or more dies 16 directly on a circuit board to also reduce the die footprint. Embodiments with vias 36 further have the capability of communicating between the top and bottom die surfaces 30 and 32.

Although the above discussion discloses various exemplary embodiments of the invention, it should be apparent that those skilled in the art can make various modifications that will achieve some of the advantages of the invention without departing from the true scope of the invention.

What is claimed is:

1. A packaged microchip comprising:
a base having a mounting surface with a given electrical interconnector;
a microchip having a plurality of side surfaces, a top surface, and a bottom surface, the microchip also having a given electrical pad on at least one of the top and bottom surfaces, one of the microchip side surfaces being generally parallel with the mounting surface of the base; and
a given solder ball secured to the given electrical pad, the given solder ball also being connected to the given electrical interconnector, the given solder ball electrically connecting the given electrical pad of the microchip and the given electrical interconnector of the base.

2. The packaged microchip as defined by claim 1 wherein the given solder ball connects between the top surface of the microchip and the base, the packaged microchip further comprising a second solder ball secured between the bottom surface of the microchip and the base.

3. The packaged microchip as defined by claim 2 wherein the mounting surface has a second electrical interconnector, the bottom surface of the microchip has a second electrical pad, the second solder ball electrically connecting the second electrical interconnector with the second electrical pad.

4. The packaged microchip as defined by claim 1 wherein the microchip comprises a via extending between the top and bottom surfaces,
the via, given electrical pad, given solder ball, and given electrical interconnector forming a conductive path.

5. The packaged microchip as defined by claim 1 further comprising a base via extending through the base, the base via including the given electrical interconnector.

6. The packaged microchip as defined by claim 1 further comprising a cover secured to the base, the cover and base forming a cavity containing the microchip.

7. The packaged microchip as defined by claim 1 wherein the microchip comprises a MEMS device.

8. The packaged microchip as defined by claim 1 further comprising additional components secured to the base.

9. The packaged microchip as defined by claim 1 wherein the side surface that is generally parallel with the mounting surface is free of electrical pads.

10. The packaged microchip as defined by claim 1 wherein the base comprises one of a substrate, carrier, and a laminate.

11. The packaged microchip as defined by claim 1 wherein one of the microchip side surfaces is mounted generally flush with the mounting surface of the base.

12. A packaged microchip comprising:
a base having a mounting surface with a given electrical interconnector;
a microchip having a plurality of side surfaces, a top surface, and a bottom surface, the microchip also having a given electrical pad on at least one of the top and bottom surfaces, one of the microchip side surfaces being generally parallel with the mounting surface of the base; and
means for electrically connecting the given electrical pad of the microchip and the given electrical interconnector of the base, the means for electrically connecting also at least in part mechanically securing the microchip to the base.

13. The packaged microchip as defined by claim 12 wherein the electrically connecting means comprises a solder ball.

14. The packaged microchip as defined by claim 12 wherein the electrically connecting means connects between the top surface and the base, the packaged microchip further comprising a second means for electrically connecting between the bottom surface and the base, the second electrically connecting means also at least in part mechanically securing the microchip to the base.

15. The packaged microchip as defined by claim 12 wherein the microchip comprises a via extending between the top and bottom surfaces,
the via, given electrical pad, electrically connecting means, and given electrical interconnector forming a conductive path.

16. An apparatus comprising:
a circuit board having a mounting surface with a given electrical interconnector;
a microchip having a plurality of side surfaces, a top surface, and a bottom surface, the microchip also having a given electrical pad on at least one of the top and bottom surfaces, one of the microchip side surfaces being generally parallel with the mounting surface of the circuit board; and
a given solder ball secured to one of the top and bottom surfaces, the given solder ball also being connected to the mounting surface, the given solder ball electrically connecting the given electrical pad of the microchip and the given electrical interconnector of the circuit board.

17. The apparatus as defined by claim 16 wherein the microchip comprises a capped MEMS device.

18. The apparatus as defined by claim 16 wherein the given solder ball connects between the top surface and the circuit board, the packaged microchip further comprising a mechanical securing apparatus secured between the bottom surface of the microchip and the mounting surface of the circuit board to further stabilize the microchip.

19. The apparatus as defined by claim 18 wherein the mechanical securing apparatus comprises a solder ball.

20. The apparatus as defined by claim 16 wherein the microchip comprises a via extending between the top and bottom surfaces,
the via, given electrical pad, given solder ball, and given electrical interconnector forming a conductive path.

21. The apparatus as defined by claim 16 wherein the side surface that is generally parallel with the mounting surface is free of electrical pads.
